(19) United States
(12) Patent Application Publication
(10) Pub. No.: US 2023/0027434 A1
(43) Pub. Date: Jan. 26, 2023

(54) WINDOW FOR CIVIL AND INDUSTRIAL BUILDINGS

(71) Applicants: MAURO ZANETTI, PREDAPPIO (IT); MANUEL ZANETTI, PREDAPPIO (IT)

(72) Inventors: MAURO ZANETTI, PREDAPPIO (IT); MANUEL ZANETTI, PREDAPPIO (IT)

(21) Appl. No.: 17/768,870

(22) PCT Filed: Oct. 14, 2020
(86) PCT No.: PCT/IB2020/059632

§ 371 Date: Apr. 14, 2022

(30) Foreign Application Priority Data
Oct. 15, 2019 (IT) 102019000018806

(51) Int. Cl. E06B 9/386; E06B 3/67; H01L 31/042

(52) U.S. Cl. CPC E06B 9/386; E06B 3/67; H01L 31/042; E06B 2007/023

(57) ABSTRACT

Described is a window (1) for civil and industrial buildings, comprising a load-bearing frame (2) for a pair of sheets (3, 4) made of optically transparent material: a first sheet (3) and a second sheet (4) which have a relative face facing, respectively, towards the outside and towards the inside of a building (9) on which the window (1) is mounted. There are also means (11, 12, 13) for converting the energy of incident sunlight into electricity, by means of the photovoltaic effect interposed between the above-mentioned sheets (3, 4).

### TECHNICAL FIELD

This invention relates to a window for civil and industrial buildings, but also picture windows, French windows and the like.

### BACKGROUND ART

The need is increasingly felt for the sustainable development of society, which must pass through the daily choices made by each of us. Saving money, making one's home more efficient and protecting the environment are aims which can be achieved by following various paths: renewable sources, interventions at home or small daily actions.

In order to build our homes, offices and public buildings and—as far as possible—industrial buildings, use is made of the best technology to reduce energy waste and lower emissions harmful to the ecosystem, with a view to having both economic and environmental benefits.

Currently, very advanced insulation means are used to thermally isolate dwelling units. However, the windows or, in any case, the openings with one or more panels defined in the outer walls of a building to provide light and air to the inside, which usually also allow views towards the outside, are areas with a thermal flow density greater than the adjacent construction elements and are therefore critical points for the insulation measures which are necessary and also specified by the current regulations.

This problem is even more evident with the new architectural developments which require entrance zones for natural light which are as large as possible, at the expense of energy efficiency.

Moreover, again with a view to protecting the environment and cost saving, new buildings are designed in such a way as to facilitate the supply of energy from sources which are an alternative to fossil fuels.

### DISCLOSURE OF THE INVENTION

The aim of the invention is to overcome the above-mentioned drawbacks of known types of windows for civil and industrial buildings, allowing firstly the thermal insulation of buildings, both new and built several years ago, to be improved.

In the context of the above-mentioned purpose, an aim of the invention is to provide a window for civil and industrial buildings which can increase the supply of “clean” electricity and thermal energy to the building. Another aim of the invention is to improve the electrical and thermal efficiency of homes, offices, public buildings, industrial buildings, etc.

Yet another aim of the invention is to make a window for civil and industrial buildings using materials of common use, in such a way that the device is economically competitive.

This purpose, as well as these and other aims which will become clearer below, are achieved by a window for civil and industrial buildings, according to the invention, comprising a load-bearing frame for a pair of sheets made of optically transparent material, a first sheet having a relative face facing towards the outside of a building on which the window is mounted and a second sheet having a relative face facing towards the inside of the building, and also comprising means for converting the energy of the incident sunlight light into electricity, by means of the photovoltaic effect interposed between said sheets.

Normally, the sheets are made of glass or similar material mounted on a metal or wooden frame.

Advantageously, the conversion means comprise a solar panel equipped with solar cells and designed to extend along a direction of extension of the window, preferably at right-angles to the ground, between an open position and a closed position, wherein the open position of the panel corresponds to the configuration of minimum spatial dimensions of the screening area of said solar panel, allowing the sun's rays to penetrate inside the building to the maximum extent possible, whilst the closed position corresponds to the relative configuration of maximum dimensions and prevents as much as possible the sun's rays from entering into the building.

Preferably, the solar panel has a substantially two-dimensional extension, in such a way as to have minimum thicknesses.

The Applicant has perceived that by making the solar panel as a series of sheet-like elements equipped with solar cells extending in a transversal direction substantially at right-angles to the direction of extension of the window, this facilitates the transit operation from the open position to the closed position.

In effect, by means of movement means, these sheet-like elements pass from a configuration with maximum packaging (minimum relative distance between one sheet-like element and the next), of minimum size and maximum quantity of light entering the building to a position of maximum distance between them (minimum packaging), of maximum size and minimum quantity of light entering the building.

These solar cells comprise primary solar cells associated with a first surface of the sheet-like element, the surface facing towards the outside of the building.

In order to obtain the maximum result in terms of electricity produced, the Applicant has provided for the rotation of the sheet-like elements about the transversal direction.

Moreover, the Applicant has advantageously also mounted secondary solar cells, associated with the surface opposite the sheet-like elements with respect to the first surface. This opposite surface substantially faces towards the inside of the building, in such a way that the secondary solar cells capture the part of the radiation reflected from the primary solar cell below.

The Applicant has concluded that in order to improve the thermal efficiency of the building, even without the presence of means for converting the energy of sunlight, there can advantageously be means for conveying air in such a way as to take it away from the inside of an air heating chamber, defined between the first and the second sheets towards the inside or outside of the building, depending on the season.

Preferably, the conveying means comprise a mixer, positioned in the above-mentioned heated air chamber, which carries the air from the inside of the chamber to the inside or outside of the building using a first or a second connection channel.

In this way, in the summer the hot air formed in the chamber can be expelled out of the building, towards the outside, whilst in summer the hot air can be introduced into the building to contribute towards heating the room.

### BRIEF DESCRIPTION OF DRAWINGS

Further features and advantages of the invention are more apparent in the detailed description below, with reference to a preferred, non-limiting embodiment of the window for civil and industrial buildings, illustrated by way of example and without limiting the scope of the invention, with the aid of the accompanying drawings, in which:

FIG. 1 shows an embodiment of the window 1, in a perspective view from the outside of the building 9, in the configuration with maximum packaging;

FIG. 2 shows the window 1 of FIG. 1 in the closed position of maximum size with an enlarged detail;

FIG. 3 is a cross-section at right-angles to the ground of a first variant embodiment of the window 1, with the solar panel 11 provided with only primary solar cells 12;

FIG. 4a shows a detail of the window 1 of FIG. 3;

FIG. 4b shows a detail of a cross-section at right-angles to the ground of a second variant embodiment of the window 1, this time with the solar panel 11 equipped with primary solar cells 12 and secondary solar cells 13.

### DETAILED DESCRIPTION OF THE INVENTION

The above-mentioned drawings show a preferred embodiment of a window for civil and industrial buildings according to the invention, which is denoted its entirety with the numeral 1 and which comprises a load-bearing frame 2 for a pair of sheet 3 and 4 made of optically transparent material: a first sheet 3 having a relative face facing towards the outside of a building 9 on which the window 1 is mounted and a second sheet 4 having a relative face facing towards the inside of the building 9. The window 1 also comprises means for converting the energy of incident sunlight into electricity, by means of the photovoltaic effect interposed between the sheets 3 and 4.

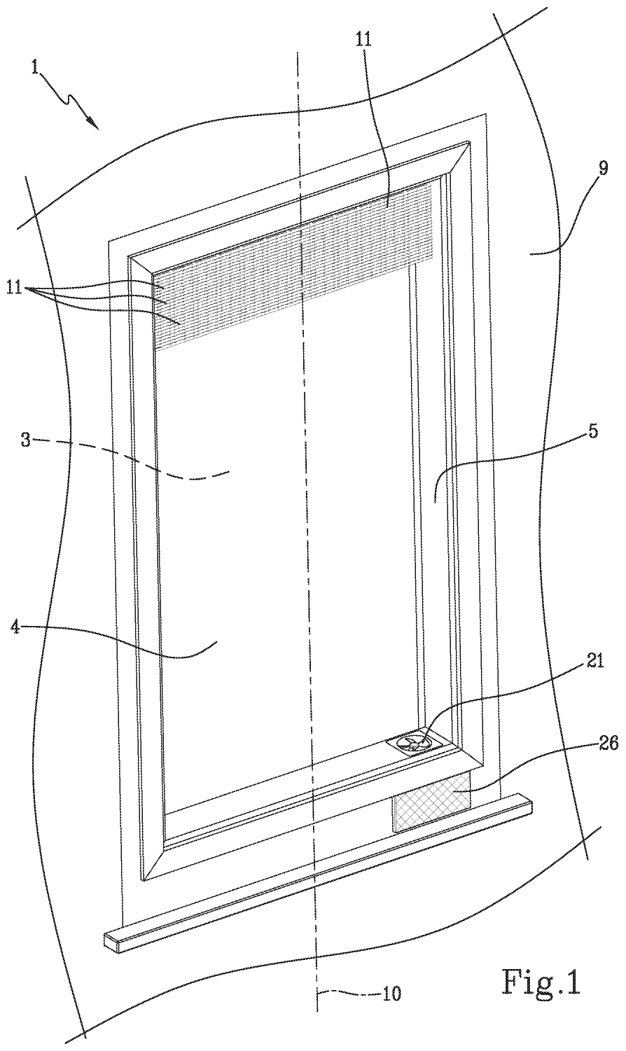

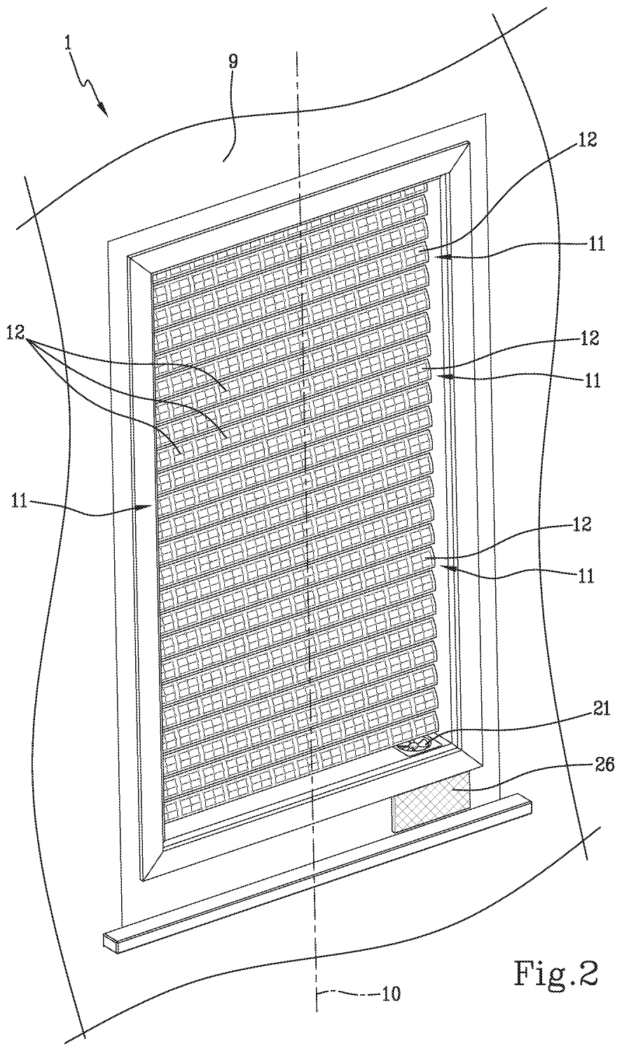

The conversion means comprise a solar panel 11, with a substantially two-dimensional extension, equipped with primary solar cells 12 (and secondary solar cells 13) and designed to extend along a direction of extension 10 of the window 1, between an open position (FIG. 1) and a closed position (FIG. 2) corresponding, respectively, to minimum and maximum spatial dimensions of the screening area of the panel 11.

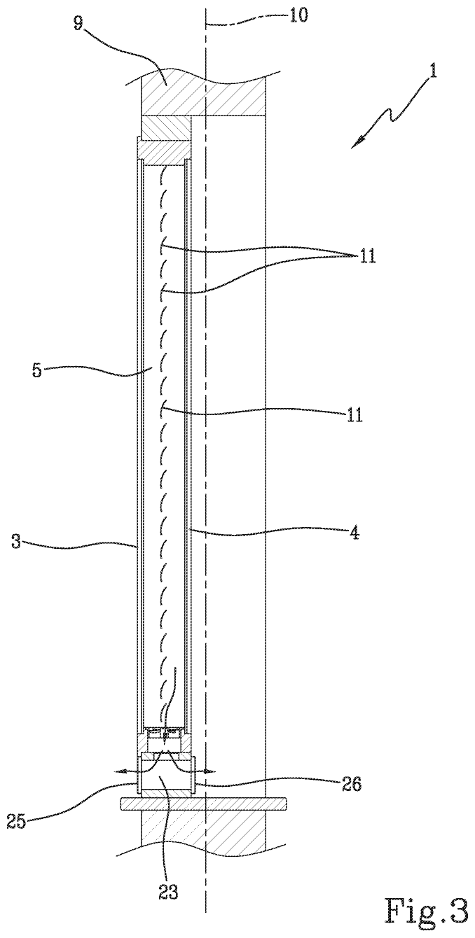

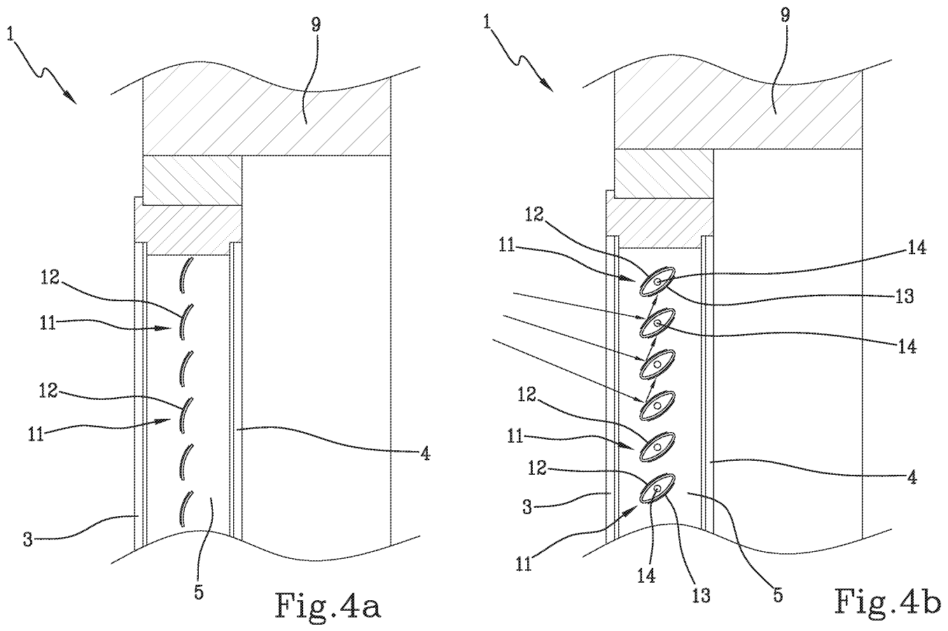

According to the preferred embodiment, the solar panel 11 comprises a series of sheet-like elements 11 extending along a transversal direction 20 substantially at right-angles to the direction of extension 10. The sheet-like elements 11 all have primary solar cells 12 on the surface intended to be directly exposed to sunlight (FIGS. 2 and 4a).

As shown in FIG. 4b, the other surface of each sheet-like element, the one opposite the surface covered by the solar cell 12, also has a secondary solar cell 13, designed to capture the solar radiation reflected by the solar cell 12 of the underlying sheet-like element.

The sheet-like elements 11 are designed to be moved along the direction of extension 10 between the open position and the closed position, by movement means, preferably electrical. Similarly to a blind of the type known as “Venetian”, this movement is such that in the open position, that is to say, with minimum dimensions, the elements 11 have a configuration with maximum packaging whilst in said closed position, that is to say, with maximum dimensions, they have a configuration of maximum relative distance.

The sheet-like elements 1 are also designed to be rotated about the transversal axis 20 by rotation means, also preferably driven electrically, depending on the solar trajectory of the place where the window 1 is installed.

The rotation means comprise two pivot elements 14 which are integral, on opposite sides, with two end portions of each element 11 and respectively free to rotate about a slot (not illustrated) formed in the frame 2, wherein at least one of the two pivots 14 has one end driven by an electric motor (not illustrated).

In the embodiment described here, the rotation is synchronised with the trajectory of the sun, according to the geographical coordinates and the date of the year.

A variant embodiment comprises the installation of light sensors connected to the rotation means.

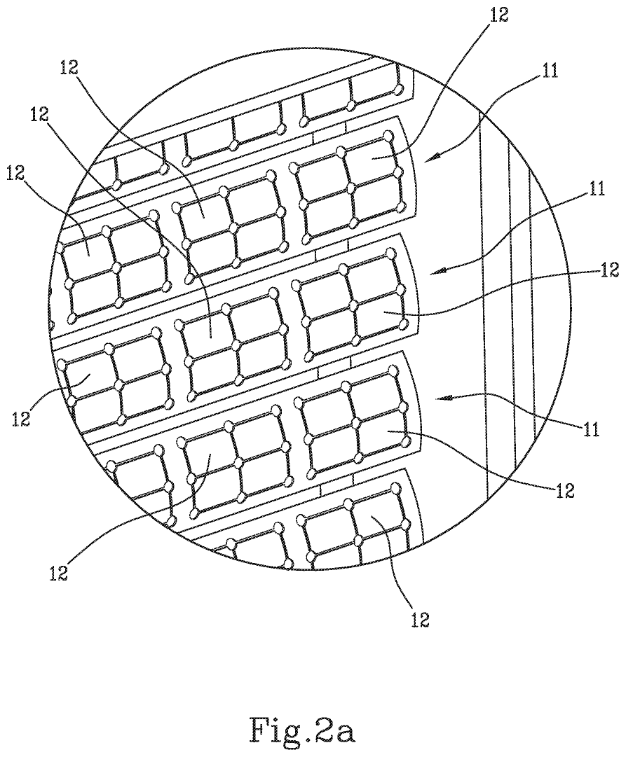

With reference to FIG. 3, the conveying means which convey hot air away from the inside of the heated air chamber 5 defined between the sheets 3 and 4, towards the inside or outside of the building 9 depending on the season, comprise a mixer 21, for example a fan 21 positioned in the heated air chamber 5, close to a first connection channel 24, or from the inside of the chamber 5 towards the outside of the building 9, by means of a second connection channel 23.

Preferably, the fan 21 is powered by the electricity produced by the means for converting the energy of the incident sunlight into electricity, that is to say, by the cells 12 (and 13), in such a way as to increase the efficiency of the device.

For this purpose, there is an outer opening 25 and/or an inner opening 26, respectively, for the flow of the hot air to the outside (in summer) or inside (in winter) of the building 9.

The openings 25 and 26 have means for opening and closing which are controlled by the fan 21 in such a way that when the fan 21 is not operating the openings prevent air from flowing from the chamber 5 to the inside or to the outside of the building 9.

The Applicant has also provided a selection system for the flowing out of the hot air (not illustrated) from the chamber 5 which comprises the alternated automated opening of only one of the two openings 25 and 26, in such a way as to prevent the simultaneous opening of the two openings 25 and 26 and therefore a passage of air from the outside to the inside of the building, and vice versa.

In order to monitor the temperature of the air in the chamber 5 and determine when it is sufficiently hot to be introduced into the building 9 during the winter or to be expelled outside the building 9 during the summer, the Applicant has mounted temperature sensor means in the chamber 5 which actuates the fan 21. In this way, as well as being sure that sufficiently hot air is removed inside rooms, energy is not wasted to power the fan if it is not necessary.

According to a variant embodiment, the window 1, which comprises a load-bearing frame 2 for a pair of sheets 3 and 4, comprises only the means for conveying air away from the inside of the chamber 5, for example the system of sheet-like elements 11 just described, without the conversion means described above.

From the above description it may be seen how the invention achieves the preset purpose and aims and in particular it should be noted that a window is made for civil and industrial buildings which allows an improved thermal insulation not only of new buildings but also those already built several years ago.

In particular, the expulsion of the hot air formed in the heated air chamber between the two sheets of glass during the summer allows the cooling of the window.

Another advantage of the invention is due to the fact that the possibility of introducing hot air into the chamber inside the building, in winter, contributes to energy saving for heating.

Another advantage of the window for civil and industrial buildings, according to the invention, is due to the fact that the photovoltaic system described guarantees a “clean” and constant electricity production, during the winter and summer, which—as well as powering the fan for conveying the hot air produced in the chamber defined by the two inner and outer sheets—can result in an surplus of energy to be introduced into the electricity grid, at the same time allowing a saving of energy coming from fossil fuels.

Lastly, the use of means which are easily available on the market and the use of common materials makes such a window economically competitive.

The invention can be modified and adapted in several ways without thereby departing from the scope of the inventive concept.

Moreover, all the details of the invention may be substituted by other technically equivalent elements.

In practice, the materials used, as well as the dimensions, may be of any type, depending on requirements, provided that they are consistent with their production purposes.

1. A window (1) for civil and industrial buildings, comprising a load-bearing frame (2) for a pair of sheets (3, 4) made of optically transparent material, a first sheet (3) having a relative face facing towards the outside of a building (9) on which the window (1) is mounted and a second sheet (4) having a relative face facing towards the inside of the building (9), and also comprising means (11, 12, 13) for converting the energy of the incident sunlight light into electricity, by means of the photovoltaic effect interposed between said sheets (3, 4).

2. The window (1) according to claim 1, wherein the conversion means (11, 12, 13) comprise a solar panel (11) equipped with solar cells (12, 13) designed to extend along a direction of extension (10) of the window (1), between an open position and a closed position, corresponding, respectively, to minimum and maximum spatial dimensions of the screening area of said solar panel (11).

3. The window (1) according to claim 2, wherein said solar panel (11) comprises a series of sheet-like elements (11) extending along a transversal direction (20) substantially at right-angles to said direction of extension (10), at least one of said sheet-like elements (11) having primary solar cells (12) in at least one relative surface.

4. The window (1) according to claim 3, wherein said solar cells (12, 13) comprise primary solar cells (12) associated with a first surface of said sheet-like element (11) facing towards the outside of the building (9).

5. The window (1) according to claim 4, wherein said solar cells (12, 13) comprise secondary solar cells (13) associated with the opposite surface of said sheet-like elements (11) relative to said first surface, said opposite surface facing substantially towards the inside of the building (9), in such a way that said secondary solar cells (13) capture the part of the radiation reflected by the primary solar cell (12) below.

6. The window (1) according to claim 3, wherein said sheet-like elements (11) are designed to be moved, by movement means, along said direction of extension (10) between said open position and said closed position, in such a way that in said open position of minimum dimensions they have a configuration with maximum packaging whilst in said closed position of maximum dimensions they have a configuration of maximum relative distance.

7. The window (1) according to claim 3, wherein at least one of said sheet-like elements (1) is designed to be rotated around said transversal direction (20) by rotation means depending on the solar trajectory of the place of assembly of the window (1).

8. The window (1) according to claim 1, comprising means (21, 22, 24, 23) for conveying the air away from the inside of an air heating chamber (5) defined between said sheets (3, 4).

9. The window (1) according to claim 8, wherein the conveying means (21, 22, 24, 23) comprise a mixer (21) positioned in said chamber (5) for conduction of the air from the inside of said chamber (5) towards the inside of the building (9) by means of a first connection channel (24), or from the inside of said chamber (5) towards the outside of said building (5), by means of a second connection channel (23).

10. A window (1) for civil and industrial buildings, comprising a load-bearing frame (2) for a pair of sheets (3, 4) made of optically transparent material, a first sheet (3) having a relative face facing towards the outside of a building (9) on which the window (1) is mounted and a second sheet (4) having a relative face facing towards the inside of the building (9), and also comprising means (21, 22, 24, 23) for conveying air away from the inside of an air heating chamber (5) defined between said sheets (3, 4).
